(19) United States
(12) Patent Application Publication
(10) Pub. No.: US 2026/0087199 A1
(43) Pub. Date: Mar. 26, 2026

(54) ENHANCED DIFFUSION MODEL GUIDANCE VIA MULTI-DENOISER MIXING

(71) Applicant: NVIDIA Corporation, Santa Clara, CA (US)

(72) Inventors: Peiyu Yu, Los Angeles, CA (US); Morteza Mardani, Santa Clara, CA (US); Arash Vahdat, San Mateo, CA (US)

(21) Appl. No.: 19/227,282

(22) Filed: Jun. 3, 2025

Related U.S. Application Data
(60) Provisional application No. 63/697,346, filed on Sep. 20, 2024.

(51) Int. Cl. G06F 30/20

(52) U.S. Cl. CPC G06F 30/20

(57) ABSTRACT

Diffusion models are machine learning algorithms implemented as neural network-based denoisers that are uniquely trained to generate high-quality data from an input lower-quality data. However, for complex datasets, the samples generated by a diffusion model can still fail to reproduce the quality and diversity of the training data, due to approximation errors made by the finite-capacity network. Diffusion guidance addresses this issue by steering the sampling process away from a less desired model, toward a preferred one. However, current guidance methods rely on a single additional denoiser and manual tuning of guidance weights, which is suboptimal for large, complex models and leads to inefficiencies. The present disclosure employs a mixture of denoisers to guide a diffusion model, which can increase the expressiveness of the guidance and substantially improve sample quality and diversity in the output of the diffusion model.

### CLAIM OF PRIORITY

This application claims the benefit of U.S. Provisional Application No. 63/697,346 (Attorney Docket No. NVIDP1414+/24-SC-1162US01) titled “ENHANCED DIFFUSION MODEL GUIDANCE VIA MULTI-DENOISER MIXING,” filed Sep. 20, 2024, the entire contents of which is incorporated herein by reference.

### TECHNICAL FIELD

The present disclosure relates to the inferencing process of a diffusion model.

### BACKGROUND

Diffusion models are machine learning algorithms that are capable of generating high-quality data—such as images, video, text, or audio—from scratch. Diffusion models are typically trained by adding varying amounts of (Gaussian) noise to the training data in a forward diffusion process and then learning to remove the noise in a reverse diffusion process. When the amount of noise is sufficiently large, the original data is effectively lost in the forward diffusion process. Thus, it is possible to generate completely novel data by starting from pure random noise and then following the reverse diffusion process to reveal a novel realization of clean data. In practice, this is achieved by repeatedly applying the learned diffusion model to gradually denoise the data over multiple denoising steps.

Generally, a neural network-based implementation of a denoiser will perform the denoising process. However, for complex datasets, the samples generated by a diffusion model can still fail to reproduce the quality and diversity of the training data, due to approximation errors made by the finite-capacity network. Diffusion guidance, such as classifier-free guidance (CFG) and auto-guidance, considers addressing this issue by steering the sampling process away from the less desired model, toward a preferred one. This process is achieved by linearly combining the predicted scores of the preferred model and the less desired base model during sampling, to effectively push the generated samples towards higher quality regions as long as the guidance weights and the less desired base model are properly chosen.

While CFG and auto-guidance offer a partial solution by steering the sampling process toward a preferred model, they are inherently limited. These methods rely on a single additional denoiser and manual tuning of guidance weights, which is suboptimal for large, complex models and leads to inefficiencies.

There is a need for addressing these issues and/or other issues associated with the prior art. For example, there is a need to employ a mixture of denoisers to guide a diffusion model, which can increase the expressiveness of the guidance and substantially improve sample quality and diversity in the output of the diffusion model.

### SUMMARY

A method, computer readable medium, and system are disclosed to guide inferencing of a diffusion model. A mixture model is generated from a plurality of diffusion models. Inferencing of a base diffusion model is guided using the mixture model.

### BRIEF DESCRIPTION OF THE DRAWINGS

FIG. 1 illustrates a flowchart of a method to guide inferencing of a diffusion model, in accordance with an embodiment.

FIG. 2 illustrates a system for guiding inferencing of a diffusion model, in accordance with an embodiment.

FIG. 3 illustrates method for generating a mixture model for use in guiding inferencing of a base diffusion model, in accordance with an embodiment.

FIG. 4 illustrates a method for using a mixture model to guide inferencing of a base diffusion model, in accordance with an embodiment.

FIG. 5A illustrates inference and/or training logic, according to at least one embodiment;

FIG. 5B illustrates inference and/or training logic, according to at least one embodiment;

FIG. 6 illustrates training and deployment of a neural network, according to at least one embodiment;

FIG. 7 illustrates an example data center system, according to at least one embodiment.

### DETAILED DESCRIPTION

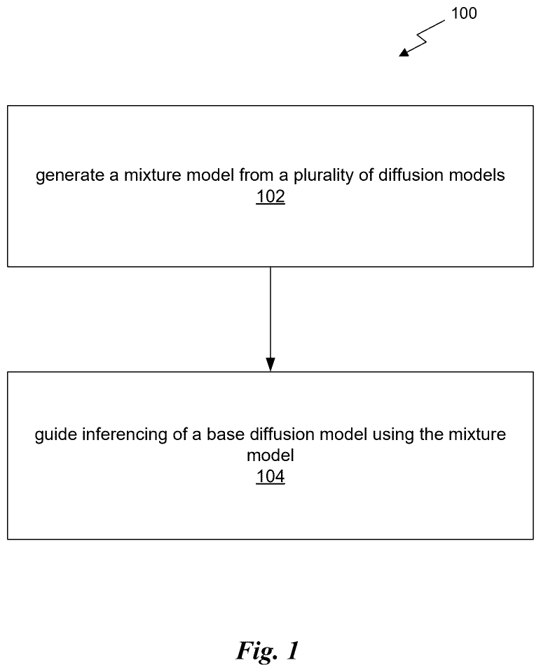

FIG. 1 illustrates a flowchart of a method 100 to guide inferencing of a diffusion model, in accordance with an embodiment. The method 100 may be performed by a device, which may be comprised of a processing unit, a program, custom circuitry, or a combination thereof, in an embodiment. In another embodiment, a system comprised of a non-transitory memory storage comprising instructions, and one or more processors in communication with the memory, may execute the instructions to perform the method 100. In another embodiment, a non-transitory computer-readable media may store computer instructions which when executed by one or more processors of a device cause the device to perform the method 100.

As mentioned, the method 100 relates specifically to an inferencing process of a diffusion model. A diffusion model refers to a machine learning model that has learned to perform a denoising process in which noise is gradually removed from a given input to result in a denoised output. In an embodiment, the diffusion model is trained with a forward diffusion process in which noise is added to training data to form noisy data and a reverse diffusion process in which the model learns to remove the noise from the noisy data over a plurality of steps. In the present embodiment, the noise refers to (e.g. random or pseudo-random) artifacts that are artificially introduced in the data. The inferencing process, in an embodiment, refers to an inference-time or test-time execution of the diffusion model in which inferenced data (i.e. output) is generated, as described below.

Returning to the method 100, in operation 102, a mixture model is generated from a plurality of diffusion models. The mixture model refers to a model generated from parameters (e.g. weights) of a plurality of other diffusion models. In an embodiment, the mixture model may be a diffusion model.

In an embodiment, the plurality of diffusion models refer to a set of diffusion models that are, at least in part, different from a base diffusion model to be guided by the mixture model (as described in more detail with reference to operation 104 below). In an embodiment, the plurality of diffusion models may be selected for use in generating the mixture model.

In an embodiment, the plurality of diffusion models may include at least one diffusion model that is inferior to the base diffusion model in at least one respect. For example, the at least one diffusion model may be inferior to the base diffusion model as a result of the at least one diffusion model diffusion model being trained over fewer iterations than the base diffusion model. As another example, the at least one diffusion model may be inferior to the base diffusion model as a result of the at least one diffusion model having fewer trainable parameters than the base diffusion model. In an embodiment, the plurality of diffusion models may include at least one model that is trained to solve a first task that is different from a second task that the base diffusion model is trained to solve.

In an embodiment, the mixture model may include a score function that is comprised of a combination of score functions from the plurality of diffusion models. In another embodiment, the mixture model may include a set of weights comprised of a combination of weights from the plurality of diffusion models. In an embodiment, the combination of weights may be determined using reinforcement learning. Thus, generating the mixture model may include determining a combination of weights from the plurality of diffusion models using reinforcement learning, and further using the combination of weights to form the mixture model.

In an embodiment, the reinforcement learning may use a reward function that is defined on preference pairs, where for example each of the preference pairs includes a winning sample, a losing sample, and a condition label. In an embodiment, the winning sample may have greater alignment with the condition label than the losing sample. In an embodiment, the winning sample may be selected as an observed sample from a training dataset and the condition label may be a class label of the observed sample. In an embodiment, the losing sample may be generated by conditional sampling from the base diffusion model or from one of the plurality of diffusion models.

In operation 104, inferencing of a base diffusion model is guided using the mixture model. The base diffusion model refers to a pretrained diffusion model that is different from the mixture model. In an embodiment, the base diffusion model may be configured to perform a particular task, such as image generation, video generation, text generation, audio generation, etc.

Guiding the inferencing of the base diffusion model using the mixture model refers to using the mixture model to cause a modification to an output of the base diffusion model. The output of the base diffusion model refers to inferenced data generated by the base diffusion model from a processing of an input. In this way, an output of the base diffusion model may be influenced (e.g. changed) using the mixture model. In an embodiment, guiding inferencing of the base diffusion model using the mixture model may improve a quality of an output of the base diffusion model.

In an embodiment, guiding inferencing of the base diffusion model using the mixture model may include processing an input by the mixture model to generate a first output, and further using the first output to guide processing of the input by the base diffusion model to generate a second output. In an embodiment, using the first output to guide processing of the input by the base diffusion model may include processing an input by the mixture model to generate a first output, processing the input by the base diffusion model to generate an intermediate output, and generating a second output as a function of the first output and the intermediate output, where a quality of the second output is greater than a quality of the intermediate output.

In an embodiment, using the first output to guide processing of the input by the base diffusion model may include processing the input by the base diffusion model to generate an intermediate output, and further boosting a difference of the intermediate output to the first output to result in the second output. In another embodiment, using the first output to guide processing of the input by the base diffusion model may include processing the input by the base diffusion model to generate an intermediate output, and further extrapolating between the first output and the intermediate output to result in the second output. In any case, when the mixture model and the base diffusion model process a same input to generate respective outputs, then the output of the base diffusion model may be influenced in any manner that is a function of the output of the mixture model.

By guiding the inferencing of the base diffusion model using the mixture model, the expressiveness of the guidance may be increased while also improving sample quality and diversity in the output of the base diffusion model. Furthermore, when using reinforcement learning to optimize weights for the mixture model, the need for exhaustive manual tuning may be avoided and in turn allows for generation of a mixture model from a larger number of diffusion models which can provide better guidance to the base diffusion model for improved quality and diversity of its generated samples.

Further embodiments will now be provided in the description of the subsequent figures. It should be noted that the embodiments disclosed herein with reference to the method 100 of FIG. 1 may apply to and/or be used in combination with any of the embodiments of the remaining figures below.

### Background on Guiding a Diffusion Model

Existing guidance for diffusion models follows Equation 1.

$${p}_{w} ( {x}_{0} \vert c ) = {{p}_{0} ( {x}_{0} \vert c )}^{w} {{p}_{1} ( {x}_{1} \vert c )}^{( 1 - w )} \qquad Equation 1$$

where p₀ serves as the base diffusion model distribution, and p₁ is the additional model guiding the base model. p₁ is instantiated as the unconditional diffusion distribution for classfier-free guidance, and a degraded version of p₀ (i.e., also a conditional distribution) for autoguidance.

### Embodiments of the Present Disclosure

The embodiments described herein augment the base diffusion model by employing a mixture of diffusion models (also referred to as denoisers) for guidance. This can be seen as a generalization of previous diffusion guidance, where more than two diffusion models may be used for guidance and where a diverse set of diffusion models may be used to compose the mixture model.

In these embodiments, p₀ refers to the distribution corresponding with the base diffusion model, and

$${\{ {p}_{k} \}}_{k = 1}^{K}$$

refers to the K additional diffusion models included in the mixture of diffusion models (or the mixture model). Formally, a product of experts is constructed as the final mixture model aiming for better sampling quality, per Equation 2.

$${p}_{w} = {p}_{0}^{{w}_{0}} {\prod }_{k = 1}^{K} {p}_{k}^{{w}_{k}} \qquad Equation 2$$

Embodiments disclosed below describe methods for selecting which diffusion models to use for generating the mixture model as well as which diffusion model weights to be combined to form the mixture model.

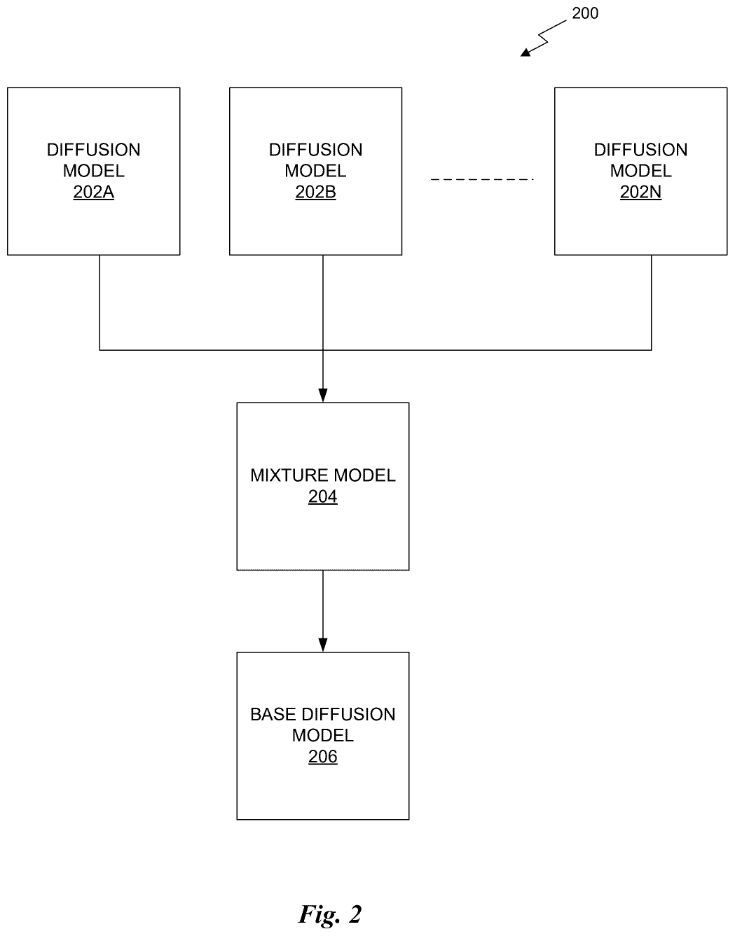

FIG. 2 illustrates a system 200 for guiding inferencing of a diffusion model, in accordance with an embodiment. The system 200 may be implemented in the context of the method 100 of FIG. 1. Components of the system 200 may be implemented in hardware, software, or a combination thereof.

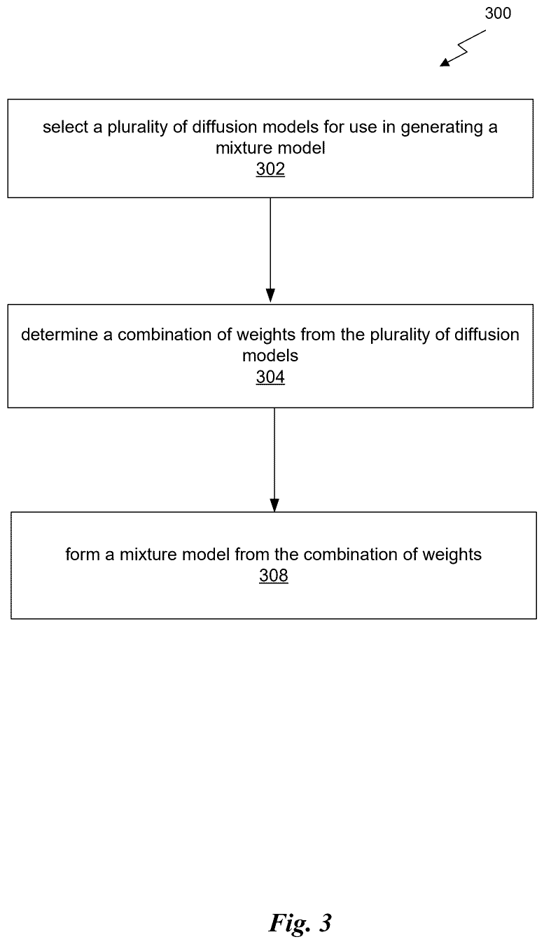

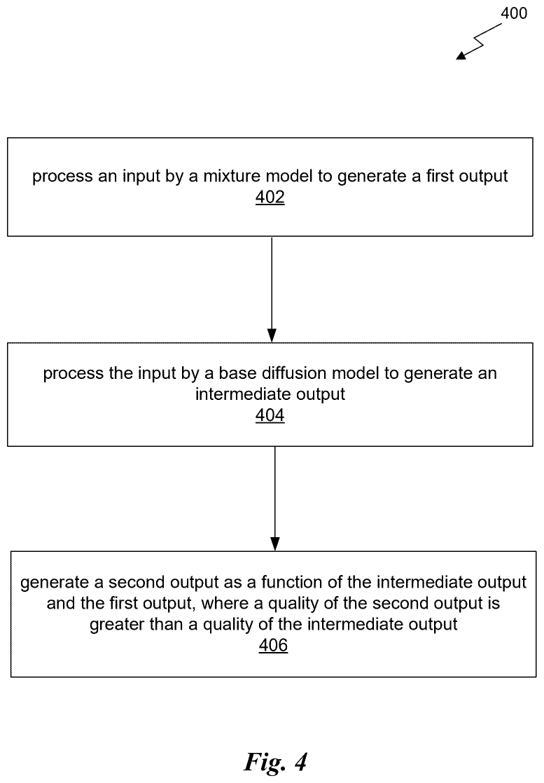

As shown, a plurality of diffusion models 202A-N are used to generate a mixture model 204. The plurality of diffusion models 202A-N may each differ from one another in at least one respect. The plurality of diffusion models 202A-N may be used to generate the mixture model 204 in accordance with the method 300 of FIG. 3, in an embodiment. The mixture model 204 may then be used to guide inferencing of the base diffusion model 206. The mixture model 204 may be used to guide inferencing of the base diffusion model 206 in accordance with the method 400 of FIG. 4, in an embodiment.

More specifically with respect to generating the mixture model 204, given the set of diffusion models 202A-N

$${\{ {p}_{k} \}}_{k = 0}^{K} ,$$

an exact set of mixture weights w=(w₀, w₁, . . . , wₖ) is determined, where

$${\sum }_{k = 1}^{K} {w}_{i} = 1 ,$$

so that p_{w} demonstrates desirable sampling quality. In an embodiment, the set of mixture weights may be determined by solving the Proximal policy optimization (PPO) optimization problem in Equation 3.

$$\begin{matrix}max {𝔼}_{c ∼ {D}_{c ,} {x}_{0} ∼ {p}_{w} ( {x}_{0} \vert c )} [ r ( c , {x}_{0} ) ] - β {𝔻}_{k 1} [ {p}_{w} ( {x}_{0} \vert c ) ‖ {p}_{ref} ( {x}_{0} \vert c ) ] \\ {p}_{w}\end{matrix} \qquad \underline{Equation 3}$$

Optimizing the above objective effectively finds a mixture distribution p_{w} such that the reward model r(c, x₀) defined on it is maximized, while regularizing the KL-divergence from a reference distribution p_{ref}. The KL-constraint keeps the resulting distribution close to the reference distribution, where the hyperparameter β controls the strength of regularization. The standard interpretation of the KL regularization is to keep the model within the distribution on which the reward is trained, namely preventing reward hacking by going off on some out-of-distribution samples, which can have high reward but be very low quality.

In this case, if the reward function r is well aligned with the sampling quality, i.e., it assigns higher values to high quality samples and vice versa, optimizing this objective can lead to a desirable set of mixture weights. In an embodiment, p_{ref} may be set as equal to p₀ or other base models, and β may be tuned appropriately for ease of optimization.

### Implicit Reward Maximization

Since there lacks a handy reward function for measuring the sampling quality in general, the Diffusion Direct Preference Optimization (DPO) framework may be used to solve for w, where the reward function is implicitly defined by the preference pairs (see Diffusion DPO described below for details). In an embodiment, p_{ref} may be set as equal to p₀ and the diffusion DPO objective corresponding with Equation 3 may be optimized per Equation 4.

$$L ( θ ) = - {𝔼}_{( {x}_{w 0} , {x}_{l 0} ) ∼ D , t ∼ U ( 0 , T ) , {x}_{wt} ∼ q ( {X}_{wt} \vert {X}_{w 0} ) , {x}_{lt} ∼ q ( {X}_{lt} \vert {X}_{l 0} )} log σ ( - β Tw ( {λ}_{t} ) ( {‖ {ϵ}^{w} - {ϵ}_{θ} ( {x}_{t}^{w} , t ) ‖}_{2}^{2} - {‖ {ϵ}^{w} - {ϵ}_{ref} ( {x}_{t}^{w} , t ) ‖}_{2}^{2} - ( {‖ {ϵ}^{l} - {ϵ}_{θ} ( {x}_{t}^{l} , t ) ‖}_{2}^{2} - {‖ {ϵ}^{l} - {ϵ}_{ref} ( {x}_{t}^{l} , t ) ‖}_{2}^{2} ) ) ) \qquad \underline{Equation 4}$$

Algorithm 1 below summarizes the optimization of mixture weights using DPO.

Importantly, the way that the preference pairs are constructed has significant influences on the learned mixture model. Specifically, each preference pair in the Diffusion DPO framework consists of a “winning” sample and a “losing” sample, together with a condition label corresponding with this pair of samples. Typically, the “winning” sample is considered to be more consistent or aligned with the condition label than the “losing” sample. In the present set-up, the observed images from the dataset are used as the winning samples, and their corresponding class labels as the condition labels. For the losing samples, different strategies may be used for collecting the data, such as:
i) The losing sample may be created by conditional sampling from only the based diffusion (main) model.
ii) An ensemble of losing samples can be created by conditional sampling from all the plurality of diffusion models (mixture components) being used to generate the mixture model.

Option ii) gives K-times as many preference pairs compared with the option i). K is the number of the mixture components.

Algorithm 1

```
$Input : D = {\{ {( {x}_{0}^{w} , {x}_{0}^{l} , c )}_{i} \}}_{i = 1}^{N} , pertrained denoisers {\{ {θ}_{k} \}}_{k = 1}^{K} , init . W .$
Output: w
$For each {( {x}_{0}^{w} , {x}_{0}^{l} , c )}_{i} in D , do$
  $sample {x}_{t}^{w} ∼ q ( {x}_{σ}^{w} \vert {x}_{σ 0}^{w} ) , {x}_{t}^{l} ∼ q ( {x}_{σ}^{l} \vert {x}_{0}^{′} c )$
  mix the score D_{w} (x_{σ} + n, σ, c) = Σₖ₌₁ wₖ(σ)D_{θk}(x_{σ} + n, σ, c)
  $calculate {Δ}^{w} = {‖ {x}_{0}^{w} - {D}_{w} ( {x}_{σ}^{w} + n , σ , c ) ‖}_{2}^{2} - ‖ {x}_{0}^{w} - {D}_{ref} ( {x}_{σ}^{w} + n , σ , c ) {‖}_{2}^{2}$
  $minimize {Δ}^{l} = {‖ {x}_{0}^{l} - {D}_{w} ( {x}_{σ}^{l} + n , σ , c ) ‖}_{2}^{2} - {‖ {x}_{0}^{l} - {D}_{ref} ( {x}_{σ}^{w} + n , σ , c ) ‖}_{2}^{2}$
  $minimize L ( w ) = - {𝔼}_{θ , n} [ log σ ( - β Tw ( {λ}_{t} ) ( {Δ}^{w} - {Δ}^{l} ) ) ]$
  until convergence
return w
```

### Diffusion DPO

### Reward Modeling

In an embodiment, ranked pairs (x_{w0}, xₗ₀) are accessed which have been generated from some conditioning c, denoted as x_{w0}>xₗ₀|c, where x_{w0} and xₗ₀ represent the “winning” and “losing” samples. The Bradley-Terry (BT) model stipulates to write human preferences per Equation 5.

$${p}_{B T} ( {x}_{w 0} > {x}_{l 0} \vert c ) = σ ( r ( c , {x}_{w 0} ) - r ( c , {x}_{l 0} ) ) \qquad \underline{Equation 5}$$

where σ is the sigmoid function. r(c, x_{w0})∈ [symbol] denotes the reward model, describing the preference of a critic (e.g., human annotator). A straight forward way to approximate the ground-truth reward r(c, x_{w0}) is parameterizing the reward function with a neural network as rØ(c, x_{w0}), and estimate the parameters via maximum likelihood training using binary classification, per Equation 6.

$${L}_{B T} ( ∅ ) = - {𝔼}_{c} , {x}_{w 0} , {x}_{l 0} [ log σ ( {r}_{∅} ( c , {x}_{w 0} ) - {r}_{∅} ( c , {x}_{l 0} ) ) \qquad \underline{Equation 6}$$

where the condition c and ranked pairs x_{w0}, xₗ₀ are typically from a pre-collected dataset with human-annotated labels.
   Reinforcement Learning with Human Feedback (RLHF)

RLHF aims to optimize a conditional distribution p_{θ}(x₀|c) (conditioning c˜D_{c}) such that the reward model r(c, x_{w0}) defined on it is maximized, while regularizing the KL-divergence from a reference distribution p_{ref}, which keeps the resulting distribution close to the reference distribution per Equation 7.

$$\begin{matrix}max {𝔼}_{c ∼ {D}_{c} , {x}_{0} ∼ {p}_{θ} ( {x}_{0} \vert c )} [ r ( c , {x}_{0} ) ] - β {𝔻}_{k 1} [ {p}_{θ} ( {x}_{0} \vert c ) ‖ {p}_{ref} ( {x}_{0} \vert c ) ] \\ {p}_{θ}\end{matrix} \qquad \underline{Equation 7}$$

The hyperparameter β controls the weight of regularization. The standard interpretation of the KL regularization is to keep the model within the distribution on which the reward is trained. I.e., preventing reward hacking by going off on some out-of-distribution samples, which can have high reward, but be very low quality.

### DPO Objective

The unique global optimal solution

$${p}_{θ}^{*}$$

of Equation 7 takes the form shown in Equation 8.

$${p}_{θ}^{*} ( {x}_{0} \vert c ) = {p}_{ref} ( {x}_{0} \vert c ) exp ( \frac{r ( c , {x}_{0} )}{β} ) / Z ( c ) \qquad \underline{Equation 8}$$

$$where Z ( c ) = {\sum }_{{x}_{0}} {p}_{r e f} ( {x}_{0} \vert c ) exp ( \frac{r ( c , {x}_{0} )}{β} )$$

is the partition function. This points to a useful parameterization of the reward function (taking the logarithm of both sides and re-arranging the terms) per Equation 9.

$$r ( c , {x}_{0} ) = β log \frac{{p}_{θ}^{*} ( {x}_{0} \vert c )}{{p}_{ref} ( {x}_{0} \vert c )} + β log Z ( c ) \qquad \underline{Equation 9}$$

Plug this parameterization of reward function into Bradly-Terry model objective as in Equation 6, the reward objective becomes that shown in Equation 10.

$${L}_{DPO} ( θ ) = - {𝔼}_{c , {x}_{wo} , {x}_{l 0}} [ log σ ( β log \frac{{p}_{θ} ( {x}_{w 0} \vert c )}{{p}_{r e f} ( {x}_{w 0} \vert c )} - β log \frac{{p}_{θ} ( {x}_{l 0} \vert c )}{{p}_{r e f} ( {x}_{l 0} \vert c )} ) ] \qquad \underline{Equation 10}$$

Based on Equation 10, instead of first optimizing the reward function r_{φ} and then finetuning the model with RL algorithms such as PPO, the model may be directly optimized for the optimal conditional distribution p_{θ}(x₀|c).

### DPO Diffusion Objective

In adapting DPO to diffusion models, an embodiment assumes a dataset D={(c, x_{w0}, xₗ₀)} of text prompt condition c with a pairs of images with preference label x_{w0}>xₗ₀. An embodiment aims to improve the reference model p_{ref} to p_{θ}, which is better aligned to the preference label compared with p_{ref}.

There are two major challenges for adapting DPO to diffusion models: i) the primary challenge is that the parameterized distribution p_{θ}(x₀|c) is not tractable, as it needs to marginalize out all possible diffusion paths (x₁, . . . x_{T}) connecting to x₀; ii) to optimize the objective we must sample x_{1:T}˜p_{θ}(x_{1:T}|x₀), which is inefficient as it requires sampling the whole reverse diffusion path.

In an embodiment, these challenges may be addressed by i) resorting to the Evidence Lower Bound (ELBO) of the conditional distribution and ii) approximating the reserve paths with forward path. This leads to the following objective (omitting c for readability) shown in Equation 11.

$$L ( θ ) = - {𝔼}_{( {x}_{w 0} , {x}_{l 0} ) ∼ D , t ∼ U ( 0 , T ) , {x}_{wt} ∼ q ( {X}_{wt} \vert {X}_{w 0} ) ,} {x}_{lt ∼ q ( {X}_{lt} \vert {X}_{l 0} )} log σ ( - β T ( + {𝔻}_{kl} ( q ( {x}_{wt - 1} \vert {x}_{w 0 , t} ) ‖ {p}_{θ} ( {x}_{wt - 1} \vert {x}_{wt} ) ) - {𝔻}_{kl} ( q ( {x}_{wt - 1} \vert {x}_{w 0 , t} ) ‖ {p}_{ref} ( {x}_{wt - 1} \vert {x}_{wt} ) ) - {𝔻}_{kl} ( q ( {x}_{lt - 1} \vert {x}_{l 0 , t} ) ‖ {p}_{θ} ( {x}_{lt - 1} \vert {x}_{lt} ) ) + {𝔻}_{kl} ( q ( {x}_{lt - 1} \vert {x}_{lo , t} ) ‖ {p}_{ref} ( {x}_{lt - 1} \vert {x}_{lt} ) ) ) \qquad \underline{Equation 11}$$

is a draw from

$$q ( {x}_{t}^{*} \vert {x}_{0}^{*} )$$

distribution (i.e., the forward distribution).

$${λ}_{t} = {α}_{t}^{2} / {σ}_{t}^{2}$$

is the signal-to-noise ratio, w(λₜ a weighting function.
Therefore the above loss simplifies to Equation 12.

$$L ( θ ) = - {𝔼}_{( {x}_{w o} , {x}_{l 0} ) ∼ D , t ∼ U ( 0 , T ) , {x}_{wt} ∼ q ( {X}_{wt} \vert {X}_{w 0} ) , {x}_{lt} ∼ q ( {X}_{lt} \vert {X}_{l 0} )} log σ ( - β Tw ( {λ}_{t} ) ( {‖ {ϵ}^{w} - {ϵ}_{θ} ( {x}_{t}^{w} , t ) ‖}_{2}^{2} - {‖ {ϵ}^{w} - {ϵ}_{ref} ( {x}_{t}^{w} , t ) ‖}_{2}^{2} - ( {‖ {ϵ}^{l} - {ϵ}_{θ} ( {x}_{t}^{l} , t ) ‖}_{2}^{2} - {‖ {ϵ}^{l} - {ϵ}_{ref} ( {x}_{t}^{l} , t ) ‖}_{2}^{2} ) ) ) \qquad \underline{Equation 12}$$

FIG. 3 illustrates method 300 for generating a mixture model for use in guiding inferencing of a base diffusion model, in accordance with an embodiment. The mixture model may be that described in any of the embodiments above.

In operation 302, a plurality of diffusion models are selected for use in generating a mixture model. In operation 304, a combination of weights are determined from the plurality of diffusion models. In operation 306, the mixture model is formed using the combination of weights.

FIG. 4 illustrates a method 400 for using a mixture model to guide inferencing of a base diffusion model, in accordance with an embodiment. The mixture model and the base diffusion model may be those described above with reference to FIG. 2. The mixture model may be that formed in accordance with the method 300 of FIG. 3.

In operation 402, an input is processed by a mixture model to generate a first output. In operation 404, the input is processed by a base diffusion model to generate an intermediate output. In operation 406, a second output is generated as a function of the intermediate output and the first output, where a quality of the second output is greater than a quality of the intermediate output.

### Machine Learning

Deep neural networks (DNNs), including deep learning models, developed on processors have been used for diverse use cases, from self-driving cars to faster drug development, from automatic image captioning in online image databases to smart real-time language translation in video chat applications. Deep learning is a technique that models the neural learning process of the human brain, continually learning, continually getting smarter, and delivering more accurate results more quickly over time. A child is initially taught by an adult to correctly identify and classify various shapes, eventually being able to identify shapes without any coaching. Similarly, a deep learning or neural learning system needs to be trained in object recognition and classification for it get smarter and more efficient at identifying basic objects, occluded objects, etc., while also assigning context to objects.

At the simplest level, neurons in the human brain look at various inputs that are received, importance levels are assigned to each of these inputs, and output is passed on to other neurons to act upon. An artificial neuron or perceptron is the most basic model of a neural network. In one example, a perceptron may receive one or more inputs that represent various features of an object that the perceptron is being trained to recognize and classify, and each of these features is assigned a certain weight based on the importance of that feature in defining the shape of an object.

A deep neural network (DNN) model includes multiple layers of many connected nodes (e.g., perceptrons, Boltzmann machines, radial basis functions, convolutional layers, etc.) that can be trained with enormous amounts of input data to quickly solve complex problems with high accuracy. In one example, a first layer of the DNN model breaks down an input image of an automobile into various sections and looks for basic patterns such as lines and angles. The second layer assembles the lines to look for higher level patterns such as wheels, windshields, and mirrors. The next layer identifies the type of vehicle, and the final few layers generate a label for the input image, identifying the model of a specific automobile brand.

Once the DNN is trained, the DNN can be deployed and used to identify and classify objects or patterns in a process known as inference. Examples of inference (the process through which a DNN extracts useful information from a given input) include identifying handwritten numbers on checks deposited into ATM machines, identifying images of friends in photos, delivering movie recommendations to over fifty million users, identifying and classifying different types of automobiles, pedestrians, and road hazards in driverless cars, or translating human speech in real-time.

During training, data flows through the DNN in a forward propagation phase until a prediction is produced that indicates a label corresponding to the input. If the neural network does not correctly label the input, then errors between the correct label and the predicted label are analyzed, and the weights are adjusted for each feature during a backward propagation phase until the DNN correctly labels the input and other inputs in a training dataset. Training complex neural networks requires massive amounts of parallel computing performance, including floating-point multiplications and additions. Inferencing is less compute-intensive than training, being a latency-sensitive process where a trained neural network is applied to new inputs it has not seen before to classify images, translate speech, and generally infer new information.

### Inference and Training Logic

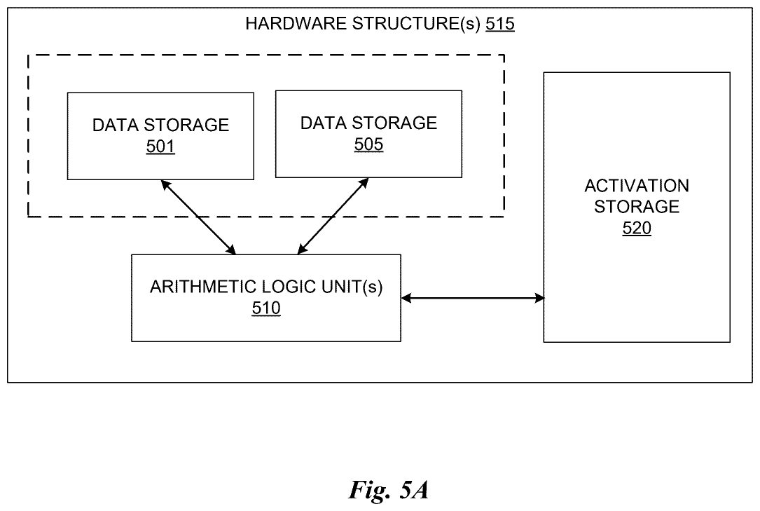

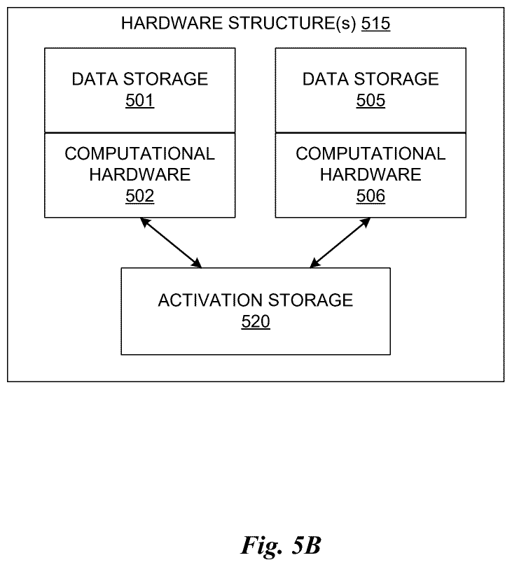

As noted above, a deep learning or neural learning system needs to be trained to generate inferences from input data. Details regarding inference and/or training logic 515 for a deep learning or neural learning system are provided below in conjunction with FIGS. 5A and/or 5B.

In at least one embodiment, inference and/or training logic 515 may include, without limitation, a data storage 501 to store forward and/or output weight and/or input/output data corresponding to neurons or layers of a neural network trained and/or used for inferencing in aspects of one or more embodiments. In at least one embodiment data storage 501 stores weight parameters and/or input/output data of each layer of a neural network trained or used in conjunction with one or more embodiments during forward propagation of input/output data and/or weight parameters during training and/or inferencing using aspects of one or more embodiments. In at least one embodiment, any portion of data storage 501 may be included with other on-chip or off-chip data storage, including a processor's L1, L2, or L3 cache or system memory.

In at least one embodiment, any portion of data storage 501 may be internal or external to one or more processors or other hardware logic devices or circuits. In at least one embodiment, data storage 501 may be cache memory, dynamic randomly addressable memory (“DRAM”), static randomly addressable memory (“SRAM”), non-volatile memory (e.g., Flash memory), or other storage. In at least one embodiment, choice of whether data storage 501 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, inference and/or training logic 515 may include, without limitation, a data storage 505 to store backward and/or output weight and/or input/output data corresponding to neurons or layers of a neural network trained and/or used for inferencing in aspects of one or more embodiments. In at least one embodiment, data storage 505 stores weight parameters and/or input/output data of each layer of a neural network trained or used in conjunction with one or more embodiments during backward propagation of input/output data and/or weight parameters during training and/or inferencing using aspects of one or more embodiments. In at least one embodiment, any portion of data storage 505 may be included with other on-chip or off-chip data storage, including a processor's L1, L2, or L3 cache or system memory. In at least one embodiment, any portion of data storage 505 may be internal or external to on one or more processors or other hardware logic devices or circuits. In at least one embodiment, data storage 505 may be cache memory, DRAM, SRAM, non-volatile memory (e.g., Flash memory), or other storage. In at least one embodiment, choice of whether data storage 505 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors.

In at least one embodiment, data storage 501 and data storage 505 may be separate storage structures. In at least one embodiment, data storage 501 and data storage 505 may be same storage structure. In at least one embodiment, data storage 501 and data storage 505 may be partially same storage structure and partially separate storage structures. In at least one embodiment, any portion of data storage 501 and data storage 505 may be included with other on-chip or off-chip data storage, including a processor's L1, L2, or L3 cache or system memory.

In at least one embodiment, inference and/or training logic 515 may include, without limitation, one or more arithmetic logic unit(s) (“ALU(s)”) 510 to perform logical and/or mathematical operations based, at least in part on, or indicated by, training and/or inference code, result of which may result in activations (e.g., output values from layers or neurons within a neural network) stored in an activation storage 520 that are functions of input/output and/or weight parameter data stored in data storage 501 and/or data storage 505. In at least one embodiment, activations stored in activation storage 520 are generated according to linear algebraic and or matrix-based mathematics performed by ALU(s) 510 in response to performing instructions or other code, wherein weight values stored in data storage 505 and/or data 501 are used as operands along with other values, such as bias values, gradient information, momentum values, or other parameters or hyperparameters, any or all of which may be stored in data storage 505 or data storage 501 or another storage on or off-chip. In at least one embodiment, ALU(s) 510 are included within one or more processors or other hardware logic devices or circuits, whereas in another embodiment, ALU(s) 510 may be external to a processor or other hardware logic device or circuit that uses them (e.g., a co-processor). In at least one embodiment, ALUs 510 may be included within a processor's execution units or otherwise within a bank of ALUs accessible by a processor's execution units either within same processor or distributed between different processors of different types (e.g., central processing units, graphics processing units, fixed function units, etc.). In at least one embodiment, data storage 501, data storage 505, and activation storage 520 may be on same processor or other hardware logic device or circuit, whereas in another embodiment, they may be in different processors or other hardware logic devices or circuits, or some combination of same and different processors or other hardware logic devices or circuits. In at least one embodiment, any portion of activation storage 520 may be included with other on-chip or off-chip data storage, including a processor's L1, L2, or L3 cache or system memory. Furthermore, inferencing and/or training code may be stored with other code accessible to a processor or other hardware logic or circuit and fetched and/or processed using a processor's fetch, decode, scheduling, execution, retirement and/or other logical circuits.

In at least one embodiment, activation storage 520 may be cache memory, DRAM, SRAM, non-volatile memory (e.g., Flash memory), or other storage. In at least one embodiment, activation storage 520 may be completely or partially within or external to one or more processors or other logical circuits. In at least one embodiment, choice of whether activation storage 520 is internal or external to a processor, for example, or comprised of DRAM, SRAM, Flash or some other storage type may depend on available storage on-chip versus off-chip, latency requirements of training and/or inferencing functions being performed, batch size of data used in inferencing and/or training of a neural network, or some combination of these factors. In at least one embodiment, inference and/or training logic 515 illustrated in FIG. 5A may be used in conjunction with an application-specific integrated circuit (“ASIC”), such as Tensorflow® Processing Unit from Google, an inference processing unit (IPU) from Graphcore™, or a Nervana® (e.g., “Lake Crest”) processor from Intel Corp. In at least one embodiment, inference and/or training logic 515 illustrated in FIG. 5A may be used in conjunction with central processing unit (“CPU”) hardware, graphics processing unit (“GPU”) hardware or other hardware, such as field programmable gate arrays (“FPGAs”).

FIG. 5B illustrates inference and/or training logic 515, according to at least one embodiment. In at least one embodiment, inference and/or training logic 515 may include, without limitation, hardware logic in which computational resources are dedicated or otherwise exclusively used in conjunction with weight values or other information corresponding to one or more layers of neurons within a neural network. In at least one embodiment, inference and/or training logic 515 illustrated in FIG. 5B may be used in conjunction with an application-specific integrated circuit (ASIC), such as Tensorflow® Processing Unit from Google, an inference processing unit (IPU) from Graphcore™, or a Nervana® (e.g., “Lake Crest”) processor from Intel Corp. In at least one embodiment, inference and/or training logic 515 illustrated in FIG. 5B may be used in conjunction with central processing unit (CPU) hardware, graphics processing unit (GPU) hardware or other hardware, such as field programmable gate arrays (FPGAs). In at least one embodiment, inference and/or training logic 515 includes, without limitation, data storage 501 and data storage 505, which may be used to store weight values and/or other information, including bias values, gradient information, momentum values, and/or other parameter or hyperparameter information. In at least one embodiment illustrated in FIG. 5B, each of data storage 501 and data storage 505 is associated with a dedicated computational resource, such as computational hardware 502 and computational hardware 506, respectively. In at least one embodiment, each of computational hardware 506 comprises one or more ALUs that perform mathematical functions, such as linear algebraic functions, only on information stored in data storage 501 and data storage 505, respectively, result of which is stored in activation storage 520.

In at least one embodiment, each of data storage 501 and 505 and corresponding computational hardware 502 and 506, respectively, correspond to different layers of a neural network, such that resulting activation from one “storage/computational pair 501/502” of data storage 501 and computational hardware 502 is provided as an input to next “storage/computational pair 505/506” of data storage 505 and computational hardware 506, in order to mirror conceptual organization of a neural network. In at least one embodiment, each of storage/computational pairs 501/502 and 505/506 may correspond to more than one neural network layer. In at least one embodiment, additional storage/computation pairs (not shown) subsequent to or in parallel with storage computation pairs 501/502 and 505/506 may be included in inference and/or training logic 515.

### Neural Network Training and Deployment

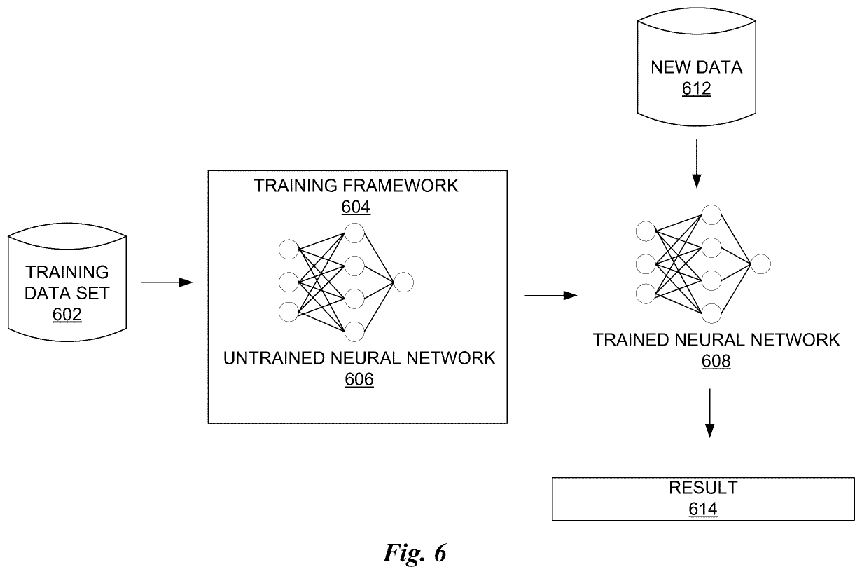

FIG. 6 illustrates another embodiment for training and deployment of a deep neural network. In at least one embodiment, untrained neural network 606 is trained using a training dataset 602. In at least one embodiment, training framework 604 is a PyTorch framework, whereas in other embodiments, training framework 604 is a Tensorflow, Boost, Caffe, Microsoft Cognitive Toolkit/CNTK, MXNet, Chainer, Keras, Deeplearning4j, or other training framework. In at least one embodiment training framework 604 trains an untrained neural network 606 and enables it to be trained using processing resources described herein to generate a trained neural network 608. In at least one embodiment, weights may be chosen randomly or by pre-training using a deep belief network. In at least one embodiment, training may be performed in either a supervised, partially supervised, or unsupervised manner.

In at least one embodiment, untrained neural network 606 is trained using supervised learning, wherein training dataset 602 includes an input paired with a desired output for an input, or where training dataset 602 includes input having known output and the output of the neural network is manually graded. In at least one embodiment, untrained neural network 606 is trained in a supervised manner processes inputs from training dataset 602 and compares resulting outputs against a set of expected or desired outputs. In at least one embodiment, errors are then propagated back through untrained neural network 606. In at least one embodiment, training framework 604 adjusts weights that control untrained neural network 606. In at least one embodiment, training framework 604 includes tools to monitor how well untrained neural network 606 is converging towards a model, such as trained neural network 608, suitable to generating correct answers, such as in result 614, based on known input data, such as new data 612. In at least one embodiment, training framework 604 trains untrained neural network 606 repeatedly while adjust weights to refine an output of untrained neural network 606 using a loss function and adjustment algorithm, such as stochastic gradient descent. In at least one embodiment, training framework 604 trains untrained neural network 606 until untrained neural network 606 achieves a desired accuracy. In at least one embodiment, trained neural network 608 can then be deployed to implement any number of machine learning operations.

In at least one embodiment, untrained neural network 606 is trained using unsupervised learning, wherein untrained neural network 606 attempts to train itself using unlabeled data. In at least one embodiment, unsupervised learning training dataset 602 will include input data without any associated output data or “ground truth” data. In at least one embodiment, untrained neural network 606 can learn groupings within training dataset 602 and can determine how individual inputs are related to untrained dataset 602. In at least one embodiment, unsupervised training can be used to generate a self-organizing map, which is a type of trained neural network 608 capable of performing operations useful in reducing dimensionality of new data 612. In at least one embodiment, unsupervised training can also be used to perform anomaly detection, which allows identification of data points in a new dataset 612 that deviate from normal patterns of new dataset 612.

In at least one embodiment, semi-supervised learning may be used, which is a technique in which in training dataset 602 includes a mix of labeled and unlabeled data. In at least one embodiment, training framework 604 may be used to perform incremental learning, such as through transferred learning techniques. In at least one embodiment, incremental learning enables trained neural network 608 to adapt to new data 612 without forgetting knowledge instilled within network during initial training.

### Data Center

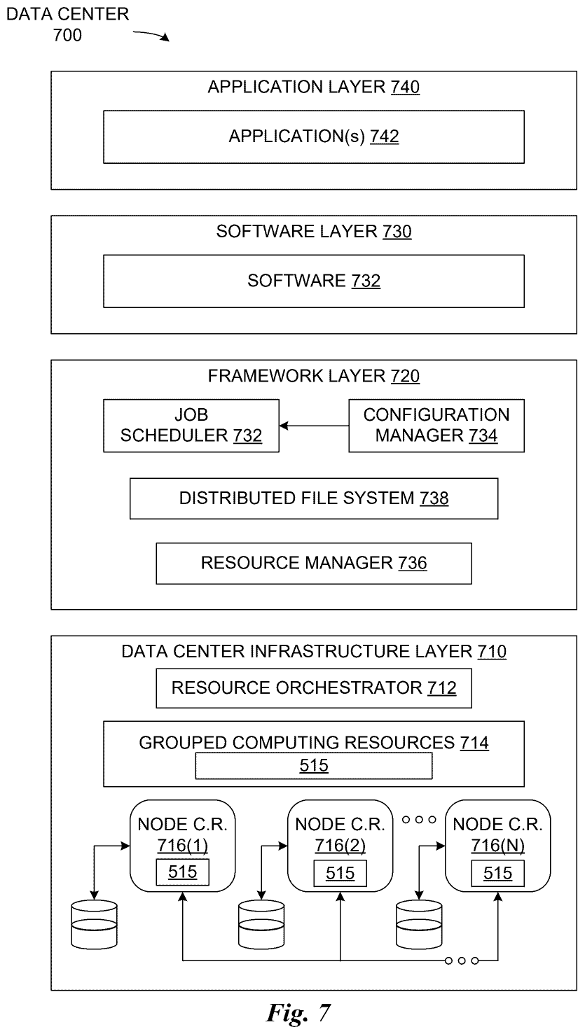

FIG. 7 illustrates an example data center 700, in which at least one embodiment may be used. In at least one embodiment, data center 700 includes a data center infrastructure layer 710, a framework layer 720, a software layer 730 and an application layer 740.

In at least one embodiment, as shown in FIG. 7, data center infrastructure layer 710 may include a resource orchestrator 712, grouped computing resources 714, and node computing resources (“node C.R.s”) 716(1)-716(N), where “N” represents any whole, positive integer. In at least one embodiment, node C.R.s 716(1)-716(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 716(1)-716(N) may be a server having one or more of above-mentioned computing resources.

In at least one embodiment, grouped computing resources 714 may include separate groupings of node C.R.s housed within one or more racks (not shown), or many racks housed in data centers at various geographical locations (also not shown). Separate groupings of node C.R.s within grouped computing resources 714 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 722 may configure or otherwise control one or more node C.R.s 716(1)-716(N) and/or grouped computing resources 714. In at least one embodiment, resource orchestrator 722 may include a software design infrastructure (“SDI”) management entity for data center 700. In at least one embodiment, resource orchestrator may include hardware, software or some combination thereof.

In at least one embodiment, as shown in FIG. 7, framework layer 720 includes a job scheduler 732, a configuration manager 734, a resource manager 736 and a distributed file system 738. In at least one embodiment, framework layer 720 may include a framework to support software 732 of software layer 730 and/or one or more application(s) 742 of application layer 740. In at least one embodiment, software 732 or application(s) 742 may respectively include web-based service software or applications, such as those provided by Amazon Web Services, Google Cloud and Microsoft Azure. In at least one embodiment, framework layer 720 may be, but is not limited to, a type of free and open-source software web application framework such as Apache Spark™ (hereinafter “Spark”) that may utilize distributed file system 738 for large-scale data processing (e.g., “big data”). In at least one embodiment, job scheduler 732 may include a Spark driver to facilitate scheduling of workloads supported by various layers of data center 700. In at least one embodiment, configuration manager 734 may be capable of configuring different layers such as software layer 730 and framework layer 720 including Spark and distributed file system 738 for supporting large-scale data processing. In at least one embodiment, resource manager 736 may be capable of managing clustered or grouped computing resources mapped to or allocated for support of distributed file system 738 and job scheduler 732. In at least one embodiment, clustered or grouped computing resources may include grouped computing resource 714 at data center infrastructure layer 710. In at least one embodiment, resource manager 736 may coordinate with resource orchestrator 712 to manage these mapped or allocated computing resources.

In at least one embodiment, software 732 included in software layer 730 may include software used by at least portions of node C.R.s 716(1)-716(N), grouped computing resources 714, and/or distributed file system 738 of framework layer 720. one or more types of software may include, but are not limited to, Internet web page search software, e-mail virus scan software, database software, and streaming video content software.

In at least one embodiment, application(s) 742 included in application layer 740 may include one or more types of applications used by at least portions of node C.R.s 716(1)-716(N), grouped computing resources 714, and/or distributed file system 738 of framework layer 720. one or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 734, resource manager 736, and resource orchestrator 712 may implement any number and type of self-modifying actions based on any amount and type of data acquired in any technically feasible fashion. In at least one embodiment, self-modifying actions may relieve a data center operator of data center 700 from making possibly bad configuration decisions and possibly avoiding underutilized and/or poor performing portions of a data center.

In at least one embodiment, data center 700 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 700. In at least one embodiment, trained machine learning models corresponding to one or more neural networks may be used to infer or predict information using resources described above with respect to data center 700 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 515 are used to perform inferencing and/or training operations associated with one or more embodiments. In at least one embodiment, inference and/or training logic 515 may be used in system FIG. 7 for inferencing or predicting operations based, at least in part, on weight parameters calculated using neural network training operations, neural network functions and/or architectures, or neural network use cases described herein.

As described herein, a method, computer readable medium, and system are disclosed to guide inferencing of a diffusion model. In accordance with FIGS. 1-4, embodiments may provide multiple diffusion models usable for performing inferencing operations and for providing inferenced data. The diffusion models may be stored (partially or wholly) in one or both of data storage 501 and 505 in inference and/or training logic 515 as depicted in FIGS. 5A and 5B. Training and deployment of the diffusion models may be performed as depicted in FIG. 6 and described herein. Distribution of the diffusion models may be performed using one or more servers in a data center 700 as depicted in FIG. 7 and described herein.

What is claimed is:

1. A method, comprising:
at a device:
generating a mixture model from a plurality of diffusion models; and
guiding inferencing of a base diffusion model using the mixture model.

2. The method of claim 1, wherein the plurality of diffusion models include at least one diffusion model that is inferior to the base diffusion model in at least one respect.

3. The method of claim 2, wherein the at least one diffusion model is inferior to the base diffusion model as a result of the at least one diffusion model diffusion model being trained over fewer iterations than the base diffusion model.

4. The method of claim 2, wherein the at least one diffusion model is inferior to the base diffusion model as a result of the at least one diffusion model having fewer trainable parameters than the base diffusion model.

5. The method of claim 1, wherein the plurality of diffusion models include at least one model that is trained to solve a first task that is different from a second task that the base diffusion model is trained to solve.

6. The method of claim 1, wherein the mixture model includes a set of weights comprised of a combination of weights from the plurality of diffusion models.

7. The method of claim 6, wherein the combination of weights is determined using reinforcement learning.

8. The method of claim 7, wherein the reinforcement learning uses a reward function that is defined on preference pairs.

9. The method of claim 8, wherein each of the preference pairs includes a winning sample, a losing sample, and a condition label.

10. The method of claim 9, wherein the winning sample has greater alignment with the condition label than the losing sample.

11. The method of claim 10, wherein the winning sample is selected as an observed sample from a training dataset and wherein the condition label is a class label of the observed sample.

12. The method of claim 10, wherein the losing sample is generated by conditional sampling from the base diffusion model.

13. The method of claim 10, wherein the losing sample is generated by conditional sampling from one of the plurality of diffusion models.

14. The method of claim 1, wherein the mixture model includes a score function that is comprised of a combination of score functions from the plurality of diffusion models.

15. The method of claim 1, wherein the plurality of diffusion models are selected for use in generating the mixture model.

16. The method of claim 1, wherein guiding inferencing of the base diffusion model using the mixture model includes:
processing an input by the mixture model to generate a first output, and
using the first output to guide processing of the input by the base diffusion model to generate a second output.

17. The method of claim 16, wherein using the first output to guide processing of the input by the base diffusion model includes:
processing the input by the base diffusion model to generate an intermediate output, and
boosting a difference of the intermediate output to the first output to result in the second output.

18. The method of claim 16, wherein using the first output to guide processing of the input by the base diffusion model includes:
processing the input by the base diffusion model to generate an intermediate output, and
extrapolating between the first output and the intermediate output to result in the second output.

19. The method of claim 1, wherein guiding inferencing of the base diffusion model using the mixture model improves a quality of an output of the base diffusion model.

20. The method of claim 1, wherein the base diffusion model is configured to perform a particular task.

21. The method of claim 20, wherein the task is image generation.

22. The method of claim 20, wherein the task is video generation.

23. The method of claim 20, wherein the task is text generation.

24. The method of claim 20, wherein the task is audio generation.

25. A system, comprising:
a non-transitory memory storage comprising instructions; and
one or more processors in communication with the memory, wherein the one or more processors execute the instructions to:
generate a mixture model from a plurality of diffusion models; and
guide inferencing of a base diffusion model using the mixture model.

26. The system of claim 25, wherein the mixture model is generated by:
determining a combination of weights from the plurality of diffusion models using reinforcement learning, and
using the combination of weights to form the mixture model.

27. The system of claim 25, wherein guiding inferencing of the base diffusion model using the mixture model includes:
processing an input by the mixture model to generate a first output,
processing the input by the base diffusion model to generate an intermediate output, and
generate a second output as a function of the first output and the intermediate output, wherein a quality of the second output is greater than a quality of the intermediate output.

28. A non-transitory computer-readable media storing computer instructions which when executed by one or more processors of a device cause the device to:
generate a mixture model from a plurality of diffusion models; and
guide inferencing of a base diffusion model using the mixture model.

29. The non-transitory computer-readable media of claim 28, wherein the mixture model is generated by:
determining a combination of weights from the plurality of diffusion models using reinforcement learning, and
using the combination of weights to form the mixture model.

30. The non-transitory computer-readable media of claim 28, wherein guiding inferencing of the base diffusion model using the mixture model includes:
processing an input by the mixture model to generate a first output,
processing the input by the base diffusion model to generate an intermediate output, and
generate a second output as a function of the first output and the intermediate output, wherein a quality of the second output is greater than a quality of the intermediate output.
